(19) United States
(12) Patent Application Publication
(10) Pub. No.: US 2025/0393187 A1
(43) Pub. Date: Dec. 25, 2025

(54) SEMICONDUCTOR DEVICE AND METHOD FOR FABRICATING THE SAME

(71) Applicant: SK hynix Inc., Gyeonggi-do (KR)

(72) Inventors: Jae Chun CHA, Gyeonggi-do (KR); Kyeong Taek KIM, Gyeonggi-do (KR); Young Jin KIM, Gyeonggi-do (KR); Yoo Jin JO, Gyeonggi-do (KR)

(21) Appl. No.: 18/961,453

(22) Filed: Nov. 27, 2024

(30) Foreign Application Priority Data
Jun. 24, 2024 (KR) 10-2024-0081769

(51) Int. Cl. H10B 12/00

(52) U.S. Cl. CPC H10B 12/053; H10B 12/34

(57) ABSTRACT

A method for fabricating a semiconductor device may include forming a trench in a substrate; forming a gate dielectric layer on a surface of the trench; forming a buried conductive layer on the gate dielectric layer; recessing the buried conductive layer to form a lower buried electrode; performing a post-processing process on the lower buried electrode; and forming an upper buried electrode on the lower buried electrode.

### CROSS-REFERENCE TO RELATED APPLICATIONS

The present application claims priority under 35 U.S.C 119(a) to Korean Patent Application No. 10-2024-0081769, filed on Jun. 24, 2024, which is incorporated herein by reference in its entirety.

### BACKGROUND

### 1. Field

Various embodiments of the present disclosure relate to a semiconductor device, and more particularly, to a semiconductor device including a buried gate, and a method for fabricating the semiconductor device.

### 2. Description of the Related Art

A metal gate electrode has been applied for high-performance of a transistor. Particularly, a buried gate type transistor requires control of a threshold voltage for a high-performance operation. The performance of the buried gate type transistor can be affected by gate induced drain leakage (GIDL) characteristics.

### SUMMARY

Embodiments of the present disclosure are directed to a semiconductor device with improved reliability, and a method for fabricating the semiconductor device.

In accordance with an embodiment of the present disclosure, a method for fabricating a semiconductor device may include forming a trench in a substrate; forming a gate dielectric layer on a surface of the trench; forming a buried conductive layer on the gate dielectric layer; recessing the buried conductive layer to form a lower buried electrode; performing a post-processing process on the lower buried electrode; and forming an upper buried electrode on the lower buried electrode.

In accordance with an embodiment of the present disclosure, a method for fabricating a semiconductor device may include forming a trench in a substrate; forming a gate dielectric layer on a surface of the trench; forming titanium nitride having a seam on the gate dielectric layer; recessing the titanium nitride to form a titanium nitride electrode; performing a thermal annealing process to polycrystallize the recessed titanium nitride; and forming a doped polysilicon electrode on the recessed and thermal annealing processed titanium.

### BRIEF DESCRIPTION OF THE DRAWINGS

FIG. 1A is a plan view illustrating a semiconductor device in accordance with an embodiment of the present disclosure.

FIG. 1B is a cross-sectional view illustrating the semiconductor device taken along line A-A′ shown in FIG. 1A.

FIG. 1C is a cross-sectional view illustrating the semiconductor device taken along line B-B′ shown in FIG. 1A.

FIG. 1D is a cross-sectional view illustrating the semiconductor device taken along line C-C′ shown in FIG. 1A.

FIGS. 2 to 15 illustrate various views of a semiconductor device formed utilizing a method for fabricating the semiconductor device in accordance with an embodiment of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the present disclosure.

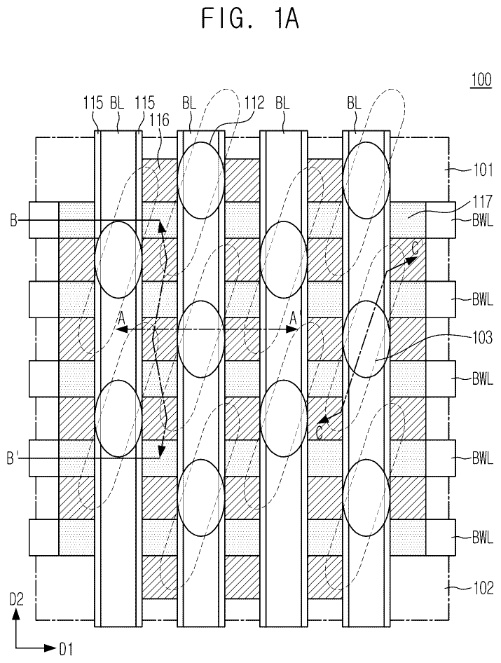

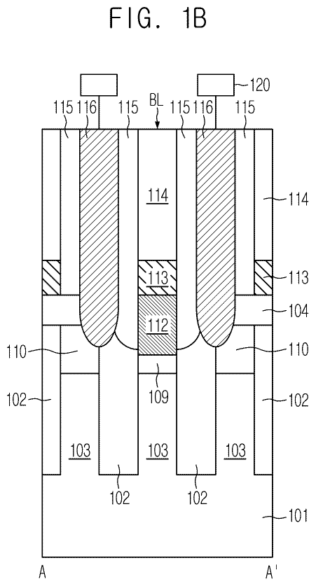

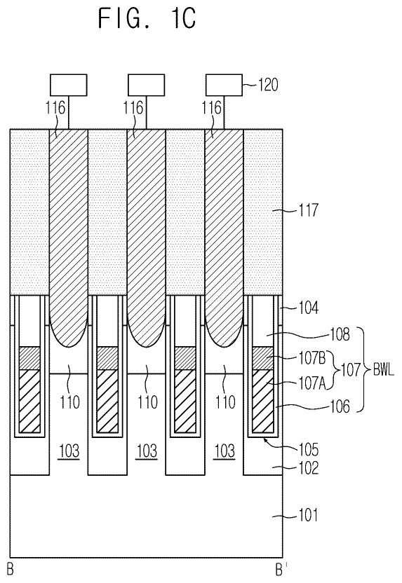

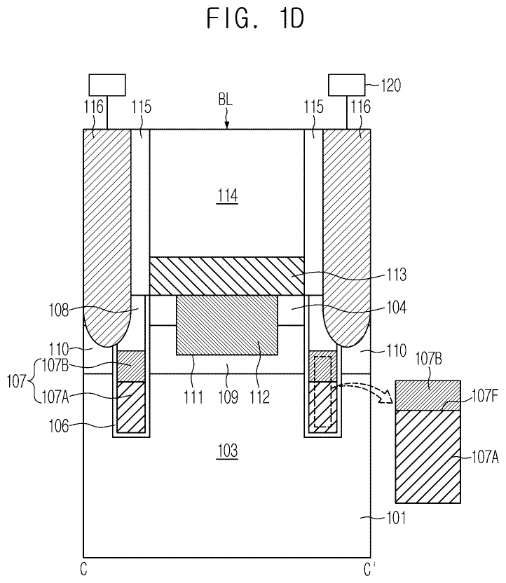

FIG. 1A is a plan view illustrating a semiconductor device 100 in accordance with an embodiment of the present disclosure. FIG. 1B is a cross-sectional view illustrating the semiconductor device 100 taken along line A-A′ shown in FIG. 1A. FIG. 1C is a cross-sectional view illustrating the semiconductor device 100 taken along line B-B′ shown in FIG. 1A. FIG. 1D is a cross-sectional view illustrating the semiconductor device 100 taken along line C-C′ shown in FIG. 1A.

Referring to FIGS. 1A to 1D, the semiconductor device 100 may include a plurality of memory cells. Each of the memory cells may include a cell transistor including a buried gate structure BWL and a bit line 113.

The semiconductor device 100 is described in detail below.

A plurality of isolation layers 102 and a plurality of active regions 103 may be formed in the substrate 101. The plurality of the active regions 103 may be defined by the plurality of isolation layers 102. The substrate 101 may be a material suitable for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof or multi-layers thereof. The substrate 101 may include another semiconductor material, such as germanium. The substrate 101 may include a III-V group semiconductor substrate, for example, a chemical compound semiconductor substrate such as gallium arsenide (GaAs). The substrate 101 may include a Silicon-On-Insulator (SOI) substrate. The isolation layers 102 may be formed by a Shallow Trench Isolation (STI) process.

A trench 105 may be formed in the substrate 101. The buried gate structure BWL may be formed in the trench 105. The trench 105 may be referred to as a “gate trench”, and the buried gate structure BWL may be referred to as a “buried word line structure”. The buried gate structure BWL may include a gate dielectric layer 106, a buried gate 107, and a gate capping layer 108. The gate dielectric layer 106 is formed on a surface of the trench 105. The buried gate 107 may be formed to partially fill the trench 105 on the gate dielectric layer 106. The gate capping layer 108 may be formed on the buried gate 107. An upper surface of the buried gate 107 may be at a lower level than a top surface of the substrate 101. The buried gate 107 may be referred to as a “buried gate electrode” or a “buried word line”. The buried gate 107 may extend in a first direction D1.

A first impurity region 109 and a second impurity region 110 may be formed in the substrate 101. The first and second impurity regions 109 and 110 may be spaced apart from each other by the trench 105. The first and second impurity regions 109 and 110 may be referred to as “source/drain regions”. The first and second impurity regions 109 and 110 may each include an N-type impurity such as arsenic (As) or phosphorus (P). Accordingly, the buried gate 107 and the first and second impurity regions 109 and 110 may become a cell transistor. The cell transistor may improve a short-channel effect due to the presence of the buried gate 107.

A bit line contact plug 112 may be formed on the substrate 101. The bit line contact plug 112 may be coupled to the first impurity region 109. The bit line contact plug 112 may be located in a bit line contact hole 111. The bit line contact hole 111 may extend to the substrate 101 through a hard mask layer 104. The hard mask layer 104 may be formed on the substrate 101. The hard mask layer 104 may include a dielectric material. The bit line contact hole 111 may expose the first impurity region 109. A lower surface of the bit line contact plug 112 may be lower than upper surfaces of the isolation layer 102 and the active region 103. The bit line contact plug 112 may be formed of polysilicon or a metal material. A portion of the bit line contact plug 112 may have a line width less than the diameter of the bit line contact hole 111. The bit line 113 may be formed on the bit line contact plug 112. A bit line hard mask 114 may be formed on the bit line 113. A stacked structure of the bit line contact plug 112, the bit line 113, and the bit line hard mask 114 may be referred to as a “bit line structure BL”. The bit line 113 may have a line shape that extends in a second direction D2 crossing the buried gate 107. A portion of the bit line 113 may be coupled to the bit line contact plug 112. The bit line 113 and the bit line contact plug 112 may have the same line width in the first direction D1. Therefore, the bit line 113 may extend in the second direction D2 while covering the bit line contact plug 112. The bit line 113 may include a metal material such as tungsten. The bit line hard mask 114 may include a dielectric material such as silicon nitride.

A spacer structure 115 may be formed on a sidewall of the bit line structure BL. The spacer structure 115 may extend to be located on a sidewall of the bit line contact plug 112. The spacer structure 115 may include silicon nitride, silicon oxide, a low-k material, or a combination thereof. The low-k material may include SiBN, SiCO, SiCN, SiBCN, or a combination thereof. In some embodiments, the spacer structure 115 may include a multi-layer spacer. For example, the spacer structure 115 may include NKON, NKNAN, NKOK, NKOKN, NKAKN, KOK, or KAK, where “N” refers to silicon nitride, “K” refers to a low-k material, “O” refers to silicon oxide, and “A” refers to an air gap. In some embodiments, an outermost spacer of the spacer structure 115 may include a low-k material.

A storage contact plug 116 may be formed between neighboring bit line structures BL. The storage contact plug 116 may be coupled to the second impurity region 110. The storage contact plug 116 may include polysilicon, metal nitride, a metal material, metal silicide, or a combination thereof. In some embodiments, polysilicon, cobalt silicide, and tungsten may be sequentially stacked in the storage contact plug 116.

From the perspective of a view in a direction parallel to the bit line structure BL, a plug isolation structure 117 may be formed between neighboring storage contact plugs 116. The plug isolation structure 117 may be formed between neighboring bit line structures BL. The neighboring storage contact plugs 116 may be separated in the second direction D2 by the plug isolation structure 117. Between the neighboring bit line structures BL, a plurality of plug isolation structures 117 may be alternately located with a plurality of storage contact plugs 116 in the second direction D2. The storage contact plugs 116 may directly contact the spacer structure 115.

A memory element 120 may be formed on the storage contact plug 116. The memory element 120 may include a capacitor including a storage node. The storage node may have a pillar shape. In some embodiments, a dielectric layer and a plate node may be further formed on the storage node. In other embodiments, the storage node may have a cylinder shape.

The plug isolation structure 117 may include an air gap, silicon oxide, silicon nitride, a low-k material, or a combination thereof. When the plug isolation structure 117 includes the low-k material, parasitic capacitance between neighboring storage contact plugs 116 with the plug isolation structure 117 interposed therebetween may be reduced. The plug isolation structure 117 may include an air gap, SiCO, SiCN, SIOCN, SiBN, SiBCN, or a combination thereof.

As described with reference to FIGS. 1A to 1D, the semiconductor device 100 may include the buried gate 107. The buried gate 107 may include a lower buried electrode 107A and an upper buried electrode 107B.

The upper buried electrode 107B may be located on the lower buried electrode 107A, and the upper buried electrode 107B may horizontally overlap with the first impurity region 109 and the second impurity region 110. The upper buried electrode 107B may partially fill the trench 105 on the lower buried electrode 107A. An upper surface height of the upper buried electrode 107B may be lower than an upper surface of the substrate 101. The upper buried electrode 107B may horizontally overlap with the first and second impurity regions 109 and 110 with the gate dielectric layer 106 interposed therebetween. That is, the first and second impurity regions 109 and 110 may each have a depth of overlapping with the upper buried electrode 107B.

The lower buried electrode 107A and the upper buried electrode 107B may be discontinuous. For example, the lower buried electrode 107A and the upper buried electrode 107B may be different materials. The lower buried electrode 107A may include a metal-based material, whereas the upper buried electrode 107B may include a non-metal material. The lower buried electrode 107A may include titanium nitride, titanium silicon nitride, tungsten, molybdenum, ruthenium, molybdenum nitride, or a combination thereof. The upper buried electrode 107B may include a semiconductor material such as polysilicon.

The lower buried electrode 107A and the upper buried electrode 107B may have different work functions. The lower buried electrode 107A may have a high work function, whereas the upper buried electrode 107B may have a low work function. The high work function may refer to a work function value greater than a mid-gap work function of silicon. The low work function may refer to a work function value less than the mid-gap work function of silicon. For example, the low work function may be less than 4.5 eV, and the high work function may be greater than 4.5 eV. The upper buried electrode 107B may include a silicon-containing material containing an N-type dopant. In an embodiment, the upper buried electrode 107B may include polysilicon doped with an N-type dopant (hereinafter, N-type doped polysilicon). The N-type doped polysilicon has a low work function. The N-type dopant may include phosphorus (Ph) or arsenic (As). The upper buried electrode 107B may horizontally overlap with the first impurity region 109 and the second impurity region 110. Because the upper buried electrode 108B has a low work function, gate-induced drain leakage (GIDL) in the first impurity region 109 and the second impurity region 110 may be suppressed.

Referring back to FIG. 1D, an interface 107F between the lower buried electrode 107A and the upper buried electrode 107B may be a flat interface. The interface 107F between the lower buried electrode 107A and the upper buried electrode 107B may provide a void-free interface. The lower buried electrode 107A may be a seamless material.

In an embodiment, the lower buried electrode 107A may be seamless titanium nitride, and the upper buried electrode 107B may be N-type doped polysilicon. The seamless titanium nitride may be polycrystalline titanium nitride.

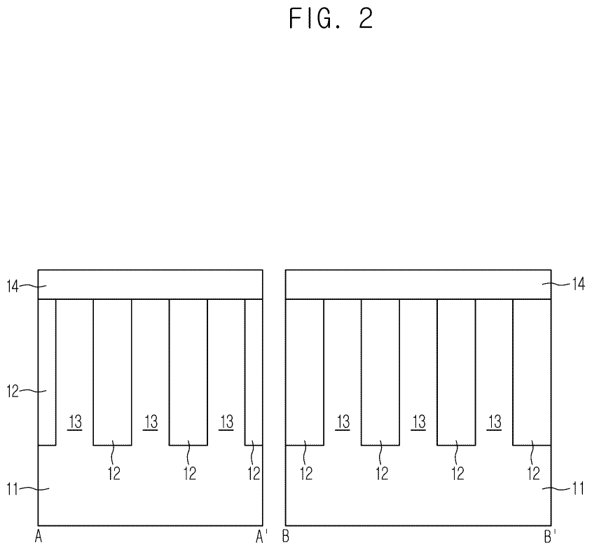

FIGS. 2 to 15 illustrate various views of a semiconductor device formed utilizing a method for fabricating the semiconductor device in accordance with an embodiment of the present disclosure. FIGS. 2 to 15 are cross-sectional views illustrating the semiconductor device 100 taken along line A-A′ and B-B′ shown in FIG. 1A.

As illustrated in FIG. 2, a plurality of isolation layers 12 may be formed in a substrate 11. A plurality of active regions 13 may be defined in the substrate 11 by the isolation layers 12. Each of the isolation layer 12 may be formed by a Shallow Trench Isolation (STI) process. The STI process is as follows. The substrate 11 is etched to form an isolation trench. The isolation trench is filled with a dielectric material, and accordingly, the isolation layer 12 is formed. The isolation layer 12 may include silicon oxide, silicon nitride, or a combination thereof. Chemical vapor deposition (CVD) or another deposition process may be used to fill the isolation trench with the dielectric material. A planarization process such as chemical-mechanical polishing (CMP) may additionally be used.

A hard mask layer 14 may be formed over the substrate 11. The hard mask layer 14 may include silicon oxide. The hard mask layer 14 may include Tetraethyl orthosilicate (TEOS).

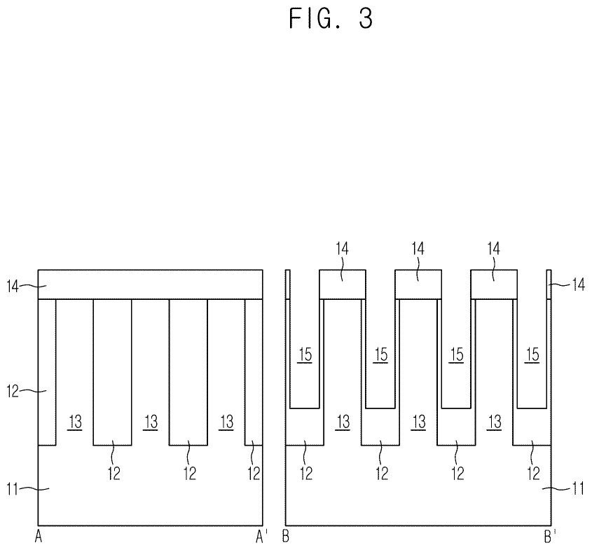

Referring to FIG. 3, a plurality of trenches 15 may be formed in the substrate 11. Each trench 15 may have a line shape crossing the active regions 13 and the isolation layer 12. A mask pattern may be formed on the substrate 11, and the trench 15 may be formed by a process of etching the hard mask layer 14 and the substrate 11 using the mask pattern as an etching mask. In order to form the trench 15, the hard mask layer 14 may be used as an etching barrier. The hard mask layer 14 may have a shape patterned by the mask pattern. A bottom surface of the trench 15 may be at a higher level than a bottom surface of the isolation layer 12.

In some embodiments, a portion of the isolation layer 12 may be recessed, and the active region 13 below the trench 15 may protrude. For example, the isolation layer 12 below the trench 15 may be selectively recessed in a longitudinal direction of the trench 15. Accordingly, a fin region may be formed below the trench 15. The fin region may be a portion of a channel region.

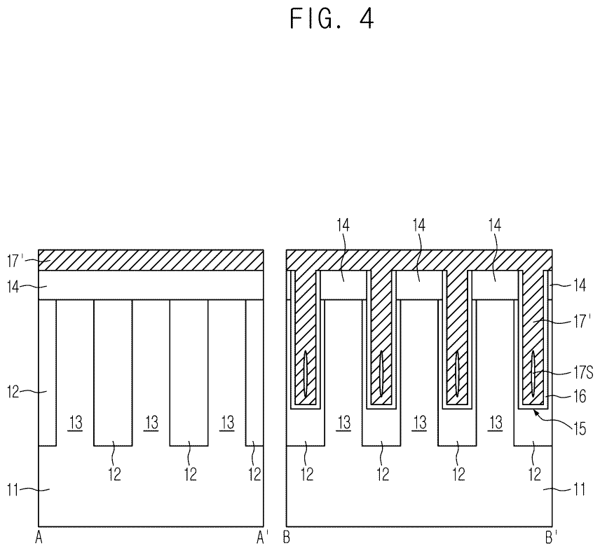

Referring to FIG. 4, a gate dielectric layer 16 may be formed on a bottom surface and sidewalls of the trench 15. Before the gate dielectric layer 16 is formed, etching damage to the surface of the trench 15 may be recovered. For example, after sacrificial oxide is formed by thermal oxidation treatment, the sacrificial oxide may be removed.

The gate dielectric layer 16 may be formed by a thermal oxidation process. For example, the gate dielectric layer 16 may be formed by oxidizing the bottom surface and sidewalls of the trench 15.

In some embodiments, the gate dielectric layer 16 may be formed by a deposition method such as chemical vapor deposition (CVD) or atomic layer deposition (ALD). The gate dielectric layer 16 may include a high-k material, oxide, nitride, oxynitride, or a combination thereof. The high-k material may include a hafnium-containing material. The hafnium-containing material may include hafnium oxide, hafnium silicon oxide, hafnium silicon oxynitride, or a combination thereof. In some embodiments, the high-k material may include lanthanum oxide, lanthanum aluminum oxide, zirconium oxide, zirconium silicon oxide, zirconium silicon oxynitride, aluminum oxide, or a combination thereof.

In some embodiments, after a liner polysilicon layer is deposited, the gate dielectric layer 16 may be formed by radically oxidizing the liner polysilicon layer.

In some embodiments, after a liner silicon nitride layer is formed, the gate dielectric layer 16 may be formed by radically oxidizing the liner silicon nitride layer.

Subsequently, a buried conductive layer 17′ may be formed on the gate dielectric layer 16. The buried conductive layer 17′ may fill the trench 15. The buried conductive layer 17′ may include a metal-based material. The buried conductive layer 17′ may include metal, metal nitride, or a combination thereof. The buried conductive layer 17′ may include titanium nitride. The buried conductive layer 17′ may include a seam 17S or a void.

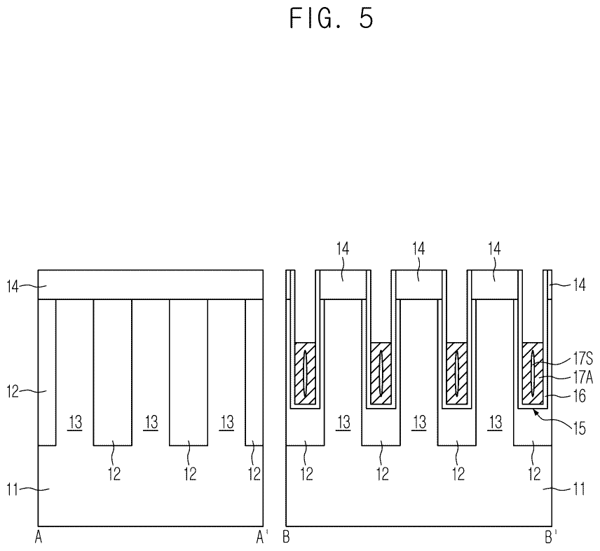

Referring to FIG. 5, a recessing process may be performed on the buried conductive layer 17′ of FIG. 4 to form a lower buried electrode 17A. As the recessing process, an etch-back process may be performed or a chemical mechanical polishing (CMP) process and the etch-back process may be sequentially performed. The lower buried electrode 17A may have a recessed shape of partially filling the trench 15. That is, an upper surface of the lower buried electrode 17A may be at a lower level than an upper surface of the active region 13. The lower buried electrode 17A may include metal, metal nitride, or a combination thereof. In some embodiments, the lower buried electrode 17A may be formed of a tungsten (W) or a titanium nitride/tungsten (TiN/W) stack. The titanium nitride/tungsten (TiN/W) stack may have a structure in which titanium nitride is conformally formed and then tungsten is used to partially fill the trench 15. As the lower buried electrode 17A, titanium nitride may be used alone, and this structure may be referred to as a “TIN Only” structure.

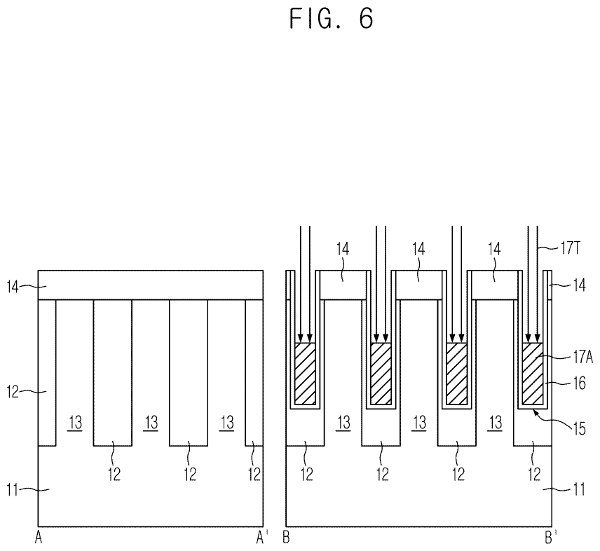

Referring to FIG. 6, the lower buried electrode 17A may be exposed to a post-treatment process 17T. The post-treatment process 17T may include a thermal process in a non-oxygen atmosphere. The non-oxygen atmosphere may refer to an atmosphere that does not contain oxygen. The post-treatment process 17T may include rapid thermal annealing (RTA), and the rapid thermal annealing may be performed in a nitrogen only atmosphere of 800° C. to 950° C. Accordingly, a surface of the lower buried electrode 17A may be prevented from being oxidized. In detail, the post-treatment process 17T is performed in an atmosphere containing only nitrogen (N₂) gas, and the temperature at which the substrate is taken out from a chamber is set to be less than 400° C. to prevent oxidation.

The seam 17S of the lower buried electrode 17A may be removed by the post-treatment process 17T, and the lower buried electrode 17A may be polycrystallized. The lower buried electrode 17A after the post-treatment process 17T may include seamless polycrystalline titanium nitride.

Before the post-treatment process 17T, the surface of the lower buried electrode 17A may be non-flat, having a V shape or a U shape. However, when the post-treatment process 17T is performed at high temperature, the flatness and roughness of the lower buried electrode 17A may be improved. Accordingly, an interface void between the lower buried electrode 17A and an upper buried electrode, which is to be formed later, may be minimized.

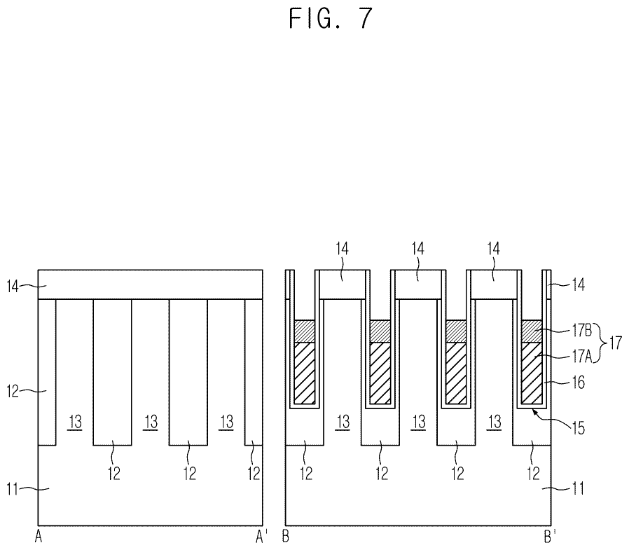

Referring to FIG. 7, an upper buried electrode 17B may be formed on the lower buried electrode 17A. Forming the upper buried electrode 17B may include depositing doped polysilicon and performing an etch-back process on the doped polysilicon. The upper buried electrode 17B may include N-type doped polysilicon. The dopant concentration of the doped polysilicon may be approximately 10²¹ atoms/cm³ or higher. The lower buried electrode 17A and the upper buried electrode 17B may constitute a buried gate 17 or a buried word line.

In some embodiments, after the etch-back process is performed to form the upper buried electrode 17B, high-temperature thermal annealing of 900° C. or higher may be performed, to maintain the dopant concentration of the upper buried electrode 17B at a high concentration. For example, the thermal annealing may be performed in a mixed gas atmosphere of nitrogen and oxygen.

As described above, as the post-treatment process 17T is performed at high temperature after the etch-back process is performed on the lower buried electrode 17A, the interface void between the lower buried electrode 17A and the upper buried electrode 17B may be removed, thereby improving reliability of the buried gate 17.

In addition, because the post-treatment process 17T is performed at high temperature before the upper buried electrode 17B is formed, an impurity in the lower buried electrode 17A may be reduced and a grain boundary size may be increased, thereby improving the quality of the buried gate 17.

In addition, because the post-treatment process 17T is performed at high temperature before the upper buried electrode 17B is formed, the contact surface between the lower buried electrode 17A and the upper buried electrode 17B may be increased.

As a comparative example, the high-temperature thermal annealing may be performed after the upper buried electrode 17B is formed. The high-temperature thermal annealing of the comparative example may be performed in a mixed atmosphere of nitrogen (N₂) and oxygen (O₂). When the high-temperature thermal annealing of the comparative example is performed, the upper buried electrode 17B may be crystallized, and the void between the lower buried electrode 17A and the upper buried electrode 17B may be removed. However, even though the high-temperature thermal annealing of the comparative example is performed, a void of the lower buried electrode 17A still remains, and the remaining void and voids existing in the grain boundary are aggregated and located at the interface between the lower buried electrode 17A and the upper buried electrode 17B, thereby deteriorating the reliability of the buried gate 17. As described above, when the post-treatment process is performed only after the upper buried electrode 17B is formed as described in the comparative example, it is difficult to remove the void existing in the lower buried electrode 17A.

In an embodiment, the post-treatment process 17T may be performed to control the interface void between the lower buried electrode 17A and the upper buried electrode 17B when the buried gate 17 is formed. For example, the thermal annealing in a nitrogen (N₂) only atmosphere of 950° C. or lower may be performed after the etch-back process is performed to form the lower buried electrode 17B. The temperature of 800° C. to 950° C. of the post-treatment process 17T may efficiently remove the void while suppressing bending of the lower buried electrode 17A. The nitrogen (N₂) only atmosphere may prevent oxidation of the lower buried electrode 17A. The high temperature of 800° C. to 950° C. may easily control the interface void between the lower buried electrode 17A and the upper buried electrode 17B.

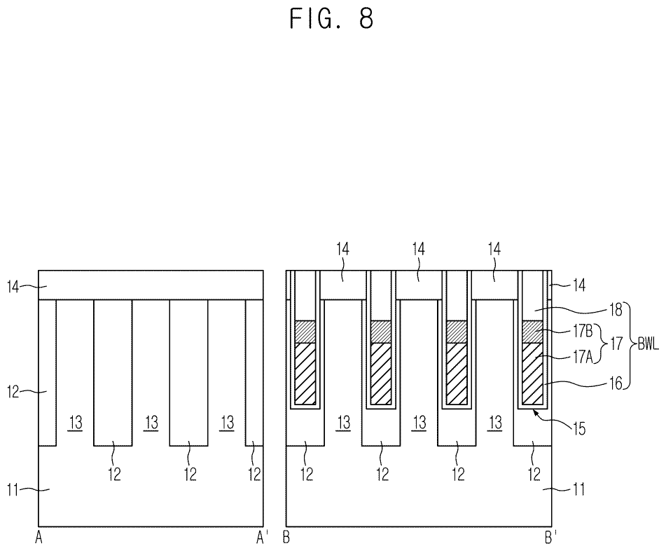

Referring to FIG. 8, a gate capping layer 18 may be formed on the upper buried electrode 17B. The gate capping layer 18 may include a dielectric material. The other portion (or remaining portion) of the trench 15 on the upper buried electrode 17B is filled with the gate capping layer 18. The gate capping layer 18 may include silicon nitride. In some embodiments, the gate capping layer 18 may include silicon oxide. In some embodiments, the gate capping layer 18 may have a nitride-oxide-nitride (NON) structure. An upper surface of the gate capping layer 18 may be at the same level as an upper surface of the hard mask layer 14. To this end, a chemical mechanical polishing (CMP) process may be performed when the gate capping layer 18 is formed.

Through a series of processes described above, a buried gate structure BWL may be formed in the trench 15. The buried gate structure BWL may include the gate dielectric layer 16, the lower buried electrode 17A, the upper buried electrode 17B, and the gate capping layer 18.

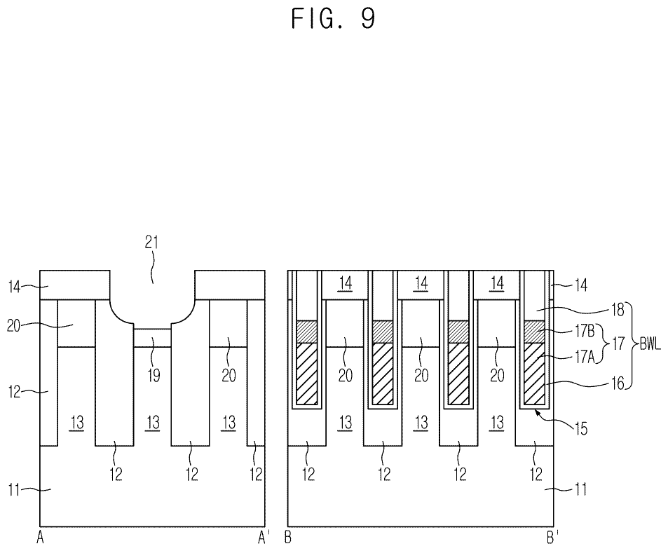

Referring to FIG. 9, impurity regions 19 and 20 may be formed. The impurity regions 19 and 20 may be formed by a doping process such as implantation. The impurity regions 19 and 20 may include a first impurity region 19 and a second impurity region 20. The first and second impurity regions 19 and 20 may be doped with the same conductivity type of impurities. The first and second impurity regions 19 and 20 may have the same depth. In some embodiments, the first impurity region 19 may be deeper than the second impurity region 20. The first and second impurity regions 19 and 20 may be referred to as source/drain regions. The first impurity region 19 may be coupled to a bit line contact plug, whereas the second impurity region 20 may be coupled to a storage contact plug. The first impurity region 19 and the second impurity region 20 may be located in different active regions 13. In addition, the first impurity region 19 and the second impurity region 20 may be spaced apart from each other by the trench 15 and be located in the respective active regions 13.

A cell transistor of a memory cell may be formed by the lower buried electrode 17A, the upper buried electrode 17B, and the first and second impurity regions 19 and 20.

Subsequently, a bit line contact hole 21 may be formed. To form the bit line contact hole 21, the hard mask layer 14 may be etched using a contact mask. The bit line contact hole 21 may have a circle shape or an oval shape, from the perspective of a plan view. A portion of the substrate 11 may be exposed by the bit line contact hole 21. The bit line contact hole 21 may have a diameter controlled to a predetermined line width. The bit line contact hole 21 may be formed to expose a portion of the active region 13. For example, the first impurity region 19 may be exposed by the bit line contact hole 21. The bit line contact hole 21 may have a diameter greater than the width of a short axis of the active region 13. Accordingly, in an etching process of forming the bit line contact hole 21, a portion of the first impurity region 19, a portion of the isolation layer 12, and a portion of the gate capping layer 18 may be etched. The gate capping layer 18, the first impurity region 19, and the isolation layer 12 below the bit line contact hole 21 may be recessed to a predetermined depth. Accordingly, the bottom of the bit line contact hole 21 may extend into the substrate 11. As the bit line contact hole 21 extends, a surface of the first impurity region 19 may be recessed, and the top surface of the first impurity region 19 may be at a lower level than the top surface of the active region 13.

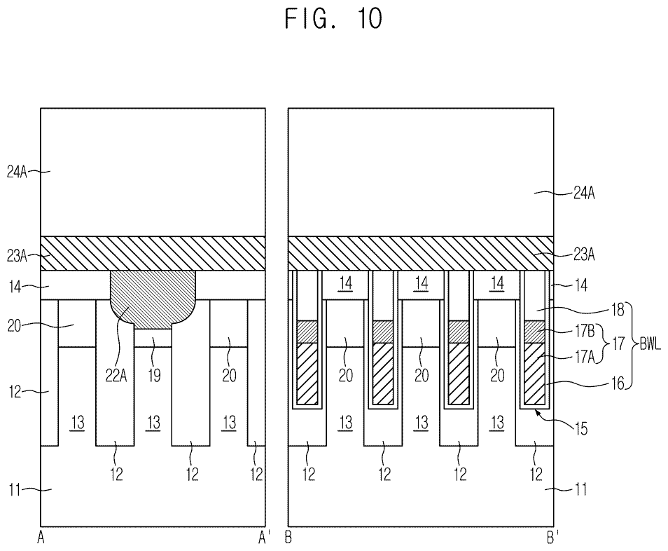

Referring to FIG. 10, a pre-plug 22A is formed. The pre-plug 22A may be formed by selective epitaxial growth (SEG). For example, the pre-plug 22A may include an epitaxial layer doped with phosphorus (P), for example, SEG SiP. The pre-plug 22A may be formed without voids by the selective epitaxial growth. In some embodiments, the pre-plug 22A may be formed by polysilicon layer deposition and a CMP process. The pre-plug 22A may fill the bit line contact hole 21. An upper surface of the pre-plug 22A may be at the same level as the upper surface of the hard mask layer 14.

A bit line conductive layer 23A and a bit line hard mask layer 24A may be stacked on the pre-plug 22A. The bit line conductive layer 23A and the bit line hard mask layer 24A may be sequentially stacked on the pre-plug 22A and the hard mask layer 14. The bit line conductive layer 23A includes a metal-containing material. The bit line conductive layer 23A may include metal, metal nitride, metal silicide, or a combination thereof. In one embodiment, the bit line conductive layer 23A may include tungsten (W). In some embodiments, the bit line conductive layer 23A may include a titanium nitride and tungsten (TiN/W) stack. In this case, the titanium nitride may serve as a barrier. The bit line hard mask layer 24A may be formed of a dielectric material having an etching selectivity with respect to the bit line conductive layer 23A and the pre-plug 22A. The bit line hard mask layer 24A may include silicon oxide or silicon nitride. In an embodiment, the bit line hard mask layer 24A may be formed of silicon nitride.

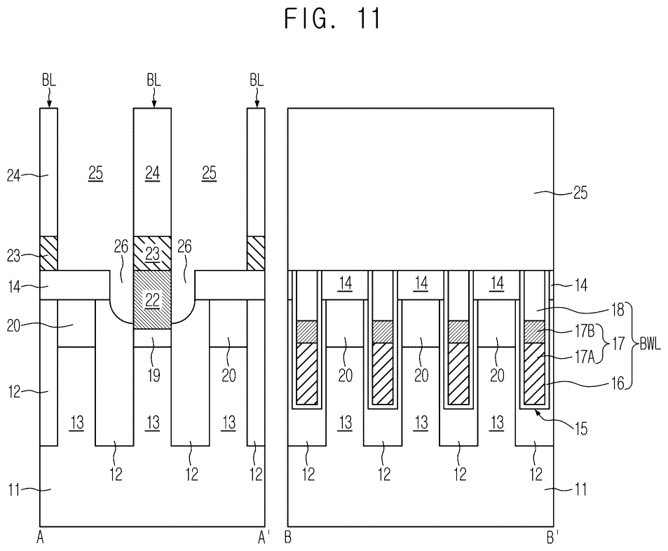

Referring to FIG. 11, a first conductive pattern structure, that is, a bit line structure BL, may be formed. The bit line structure BL may include a stack of a bit line contact plug 22, a bit line 23, and a bit line hard mask 24. The bit line contact plug 22, the bit line 23, and the bit line hard mask 24 may be formed by an etching process using a bit line mask layer.

The bit line hard mask layer 24A and the bit line conductive layer 23A of FIG. 10 are etched using the bit line mask layer as an etching barrier. Accordingly, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the pre-plug 22A may be etched to have the same line width as the bit line 23. Accordingly, the bit line contact plug 22 may be formed. The bit line contact plug 22 may be formed on the first impurity region 19. The bit line contact plug 22 may interconnect the first impurity region 19 and the bit line 23. The bit line contact plug 22 may be formed in the bit line contact hole 21. The line width of the bit line contact plug 22 is less than the diameter of the bit line contact hole 21. Therefore, gaps 26 may be defined on both sides of the bit line contact plug 22.

A structure in which the bit line contact plug 22, the bit line 23, and the bit line hard mask 24 are sequentially stacked may be referred to as the “bit line structure BL”. From the perspective of a top view, the bit line structure BL may be a pattern structure having a line shape that extends lengthwise in one direction.

A line-shaped opening 25 may be defined between neighboring bit line structures BL. The line-shaped opening 25 may be parallel to the bit line structures BL. Portions of the hard mask layer 14 may be exposed by the line-shaped opening 25.

As described above, as the bit line contact plug 22 is formed, the gap 26 is formed in the bit line contact hole 21. This is because the bit line contact plug 22 is formed by being etched to be smaller than the diameter of the bit line contact hole 21. The gap 26 does not have a surrounding shape of surrounding the bit line contact plug 22, but is independently formed on both sides of the bit line contact plug 22. Consequently, one bit line contact plug 22 and a pair of gaps 26 are located in the bit line contact hole 21, and the pair of gaps 26 are isolated by the bit line contact plug 22. A bottom surface of the gap 26 may extend into the isolation layer 12. The bottom surface of the gap 26 may be at a higher level than a recessed upper surface of the first impurity region 19.

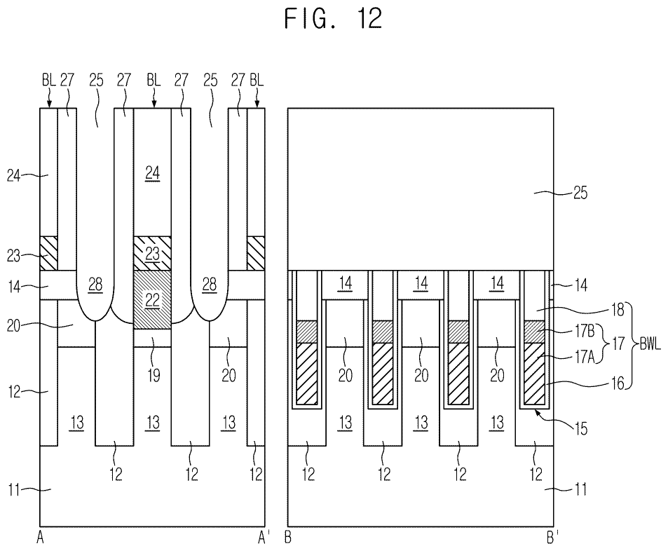

Referring to FIG. 12, spacers 27 may be formed on sidewalls of the bit line structures BL. The spacer 27 may cover both sidewalls of the bit line contact plug 22 and both sidewalls of the bit line 23. The spacer 27 may also cover both sidewalls of the bit line hard mask 24. The spacer 27 may include a dielectric material. In an embodiment, the spacer 27 may include silicon nitride. In some embodiments, the spacer 27 may have a multi-layer structure. For example, the spacer 27 may include NKON, NKNAN, NKOK, NKOKN, NKAKN, KOK, or KAK, where “N” refers to silicon nitride, “K” refers to a low-k material, “O” refers to silicon oxide, and “A” refers to an air gap. In some embodiments, an outermost spacer of the multi-layer structure of the spacer 27 may include a low-k material.

To form the spacer 27, deposition and selective etching processes may be performed on a spacer layer. The spacer 27 may be formed on a sidewall of the line-shaped opening 25.

Subsequently, lower materials may be etched to be self-aligned to the spacer 27. Accordingly, a plurality of recessed regions 28 may be formed to expose a portion of the active region 13 between the bit line structures BL. Anisotropic etching or a combination of anisotropic etching and isotropic etching may be used to form the recessed regions 28. For example, a spacer layer may be anisotropically etched between the bit line structures BL, and then a portion of the exposed active region 13 may be isotropically etched. In some embodiments, the hard mask layer 14 may also be isotropically etched. Portions of the active region 13 may be exposed by the recessed regions 28.

The recessed regions 28 may extend into the substrate 11. While the recessed regions 28 are formed, the isolation layer 12, the gate capping layer 18, and the second impurity region 20 may be recessed to a predetermined depth. Bottom surfaces of the recessed regions 28 may be at a level lower than an upper surface of the bit line contact plug 22. The bottom surfaces of the recessed regions 28 may be at a level higher than a bottom surface of the bit line contact plug 22. The line-shaped openings 25 and the recessed regions 28 may be interconnected. The vertical structure of the line-shaped openings 25 and the recessed regions 28 may be referred to as a “storage node contact hole”.

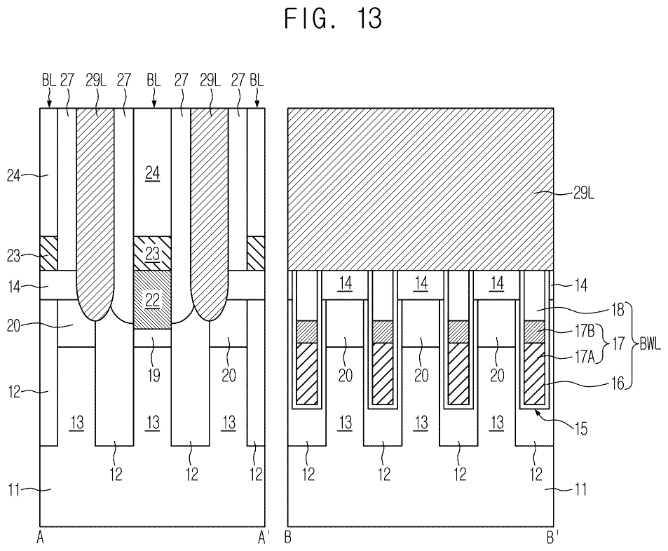

Referring to FIG. 13, line patterns 29L may be formed to fill the line-shaped openings 25 of FIG. 12. The line patterns 29L may fill the line-shaped openings 25 and the recess regions 28. The line patterns 29L may contact the second impurity regions 20. The line patterns 29L may be adjacent to the bit line structures BL. From the perspective of a top view, a plurality of line patterns 29L may be located between a plurality of bit line structures BL. The line patterns 29L may include a semiconductor material, for example, doped polysilicon.

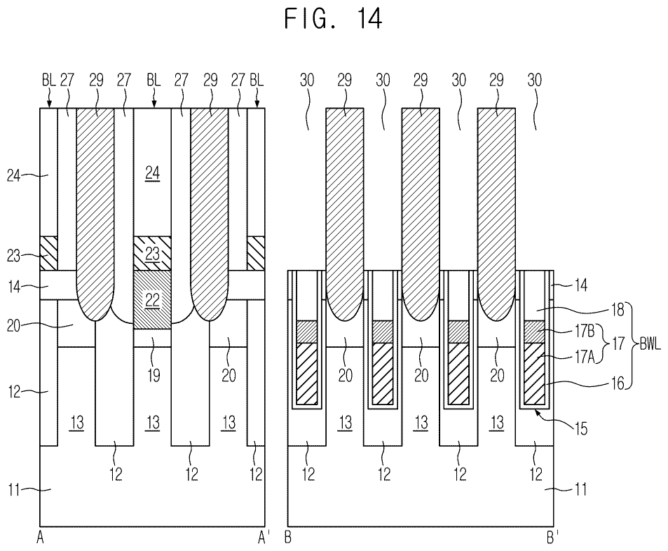

Referring to FIG. 14, the line patterns 29L of FIG. 13 may be etched using a mask layer extending in a direction crossing the line patterns 29L. Accordingly, a plurality of storage contact plugs 29 and a plurality of isolation openings 30 may be formed. From the perspective of a top view, a plurality of storage contact plugs 29 may be located between neighboring bit line structures BL, and isolation openings 30 may be disposed between the storage contact plugs 29. The storage contact plugs 29 may be referred to as “second conductive pattern structures”.

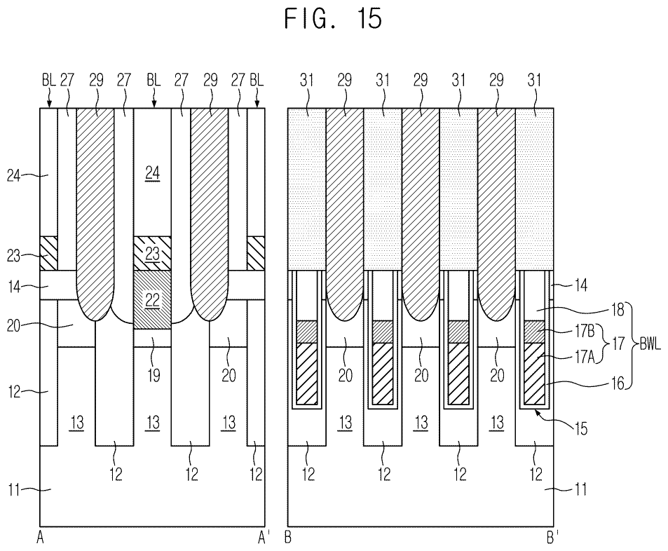

Referring to FIG. 15, plug isolation layers 31 may be formed to fill the isolation openings 30. The plug isolation layers 31 may each include silicon oxide, silicon nitride, a low-k material, an air gap, or a combination thereof.

In some embodiments, subsequently, a memory element (refer to reference numeral “150” of FIGS. 1B and 1C) may be formed on the storage contact plugs 29. For example, the memory element may form a storage node of a capacitor. In some embodiments, before the storage node of the capacitor is formed, the storage contact plugs 29 may be etched-back, and then metal silicide and a metal material may be sequentially formed on the etched-back storage contact plugs 29.

In some embodiments, the post-treatment process may be applied to a method of gap-filling a heterogeneous material in a high aspect ratio opening. For example, when titanium nitride and doped polysilicon are sequentially stacked in a high aspect ratio contact hole, the post-treatment process may be performed before the doped polysilicon is deposited, and an interface void between the titanium nitride and the doped polysilicon may be controlled.

According to various embodiments of the present disclosure, high-temperature thermal annealing is performed after an etch-back process is performed on a lower buried electrode during a buried gate fabrication process. Accordingly, an interface void between the lower buried electrode and an upper buried electrode may be removed, and the reliability of a semiconductor device may be improved.

According to various embodiments of the present disclosure, an impurity in the lower buried electrode may be reduced, and a grain boundary size may be increased, which makes it possible to improve the quality of a buried gate.

According to various embodiments of the present disclosure, a contact surface between the lower buried electrode and the upper buried electrode may be increased.

While the embodiments of the present disclosure have been illustrated and described with respect to specific embodiments and drawings, the disclosed embodiments are not intended to be restrictive. Further, it is noted that the present disclosure may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A method for fabricating a semiconductor device, the method comprising:
forming a trench in a substrate;
forming a gate dielectric layer on a surface of the trench;
forming a buried conductive layer on the gate dielectric layer;
recessing the buried conductive layer to form a lower buried electrode;
performing a post-processing process on the lower buried electrode; and
forming an upper buried electrode on the lower buried electrode.

2. The method of claim 1, wherein the post-treatment process is performed in a non-oxygen atmosphere.

3. The method of claim 1, wherein the post-treatment process is performed in a nitrogen only atmosphere.

4. The method of claim 1, wherein the post-treatment process is performed in a nitrogen atmosphere of 800° C. to 950° C.

5. The method of claim 1, wherein the upper buried electrode and the lower buried electrode have different materials.

6. The method of claim 1, wherein the lower buried electrode includes titanium nitride.

7. The method of claim 1, wherein the upper buried electrode includes doped polysilicon.

8. The method of claim 1, wherein the lower buried electrode includes titanium nitride containing a seam, and the upper buried electrode includes doped polysilicon.

9. The method of claim 1, wherein the post-treatment process is performed in a nitrogen atmosphere of 800° C. to 950° C., and the substrate is taken out at a temperature below 400° C. after the post-treatment process.

10. The method of claim 1, wherein an interface between the lower buried electrode and the upper buried electrode provides a flat interface.

11. A method for fabricating a semiconductor device, the method comprising:
forming a trench in a substrate;
forming a gate dielectric layer on a surface of the trench;
forming titanium nitride having a seam on the gate dielectric layer;
recessing the titanium nitride to form a titanium nitride electrode;
performing a thermal annealing process to polycrystallize the recessed titanium nitride; and
forming a doped polysilicon electrode on the recessed and thermal annealing processed titanium nitride.

12. The method of claim 11, wherein the thermal annealing process is performed in a non-oxygen atmosphere.

13. The method of claim 11, wherein the thermal annealing process is performed in a nitrogen only atmosphere.

14. The method of claim 11, wherein the thermal annealing process is performed in a nitrogen only atmosphere of 800° C. to 950° C.

15. The method of claim 11, wherein the thermal annealing process is performed in a nitrogen atmosphere of 800° C. to 950° C., and the substrate is taken out at a temperature below 400° C. after the thermal annealing process.

16. The method of claim 11, wherein an interface between the titanium nitride electrode and the doped polysilicon electrode provides a flat interface.
